(19) United States
(12) Patent Application Publication
(10) Pub. No.: US 2025/0287493 A1
(43) Pub. Date: Sep. 11, 2025

(54) HEAT SINK DEVICE WITH DEFINED INSERTION POINT, HEAT SINK SYSTEM, HEADLAMP, VEHICLE, AND METHOD FOR RELEASING A PRINTED CIRCUIT BOARD GLUED TO A HEAT SINK

(71) Applicant: Hella GmbH & Co. KGaA, Lippstadt (DE)

(72) Inventors: Christian Wieck, Lippstadt (DE); Thomas Wiese, Lippstadt (DE)

(21) Appl. No.: 19/069,922

(22) Filed: Mar. 4, 2025

(30) Foreign Application Priority Data
Mar. 11, 2024 (DE) 102024106813.2

(51) Int. Cl. H05K 1/02; F21S 41/19; F21Y 115/10; H05K 13/00

(52) U.S. Cl. CPC H05K 1/0201; F21S 41/192; H05K 13/0007; F21Y 2115/10; H05K 2201/066; H05K 2201/09154; H05K 2201/09827; H05K 2201/09918

(57) ABSTRACT

A heat sink is provided that has a mounting surface to which a printed circuit board is attached with an adhesive. The heat sink has a defined insertion point for a tool with which the printed circuit board is pried away from the heat sink. A heat sink system, a headlamp, a vehicle, and a method for releasing a printed circuit board glued to a heat sink using a tool are also provided.

### CROSS REFERENCE

This application claims priority to German Application No. 102024106813.2, filed Mar. 11, 2024, the entirety of which is hereby incorporated by reference.

### Field of the Invention

The present invention relates to a heat sink that has a mounting surface to which a printed circuit board can be glued, which has a defined insertion point where the printed circuit board can be released therefrom, a heat sink system, a headlamp, a vehicle, and a method for releasing the printed circuit board from the heat sink.

### BACKGROUND OF THE INVENTION

Heat sinks are usually made of a thermally conductive material, in particular copper or aluminum. The heat sink provides a large surface area where heat from components requiring cooling is discharged into the environment. There are numerous designs for heat sinks. The components that require cooling can be attached to a defined mounting surface. These components can be power electronics, power semiconductors, or a printed circuit board. These components must be glued to the heat sink with a durable and thermally conductive adhesive that can withstand the vibrations that occur during transportation or when in use. A particularly durable adhesive must be used, in particular with vehicle heat sinks, that can withstand the various mechanical effects, atmospheric conditions and temperature fluctuations. Changes in the sizes of the various components caused by temperature changes must also be accommodated by the adhesive without releasing the component from the heat sink.

There are various methods in the prior art for removing a printed circuit board from a heat sink. For example, a tool can be used to pry the circuit board away from the heat sink. The disadvantage with this is that the tool may slip on either the heat sink or the printed circuit board during the removal process. This can result in serious injuries to the mechanic, or it can damage, or even destroy, the heat sink and/or printed circuit board. It is also difficult to find an appropriate placement for the tool with which the printed circuit board can be removed from the heat sink.

### BRIEF SUMMARY OF THE INVENTION

The object of the present invention is to at least partially eliminate the above disadvantages when removing a printed circuit board from a heat sink. In particular, the object of the present invention is to create a heat sink, a heat sink system that contains a heat sink, a headlamp that contains a heat sink system with a heat sink, a vehicle that has a heat sink, and a method for easily, quickly, and inexpensively removing a printed circuit board glued to a heat sink.

The features and details described in conjunction with the heat sink also apply to the heat sink system, the headlamp, the vehicle, and/or the method obtained with invention, and vice versa, such that reference can always be made to the individual aspects of the invention with regard to the disclosure thereof, and vice versa.

A first aspect of the invention relates to a heat sink that has a mounting surface to which a printed circuit board can be glued with an adhesive. This heat sink is characterized in that it has a defined insertion point where a tool can be used for releasing the printed circuit board from the heat sink. The heat sink can have a variety of shapes. In particular, the heat sink can be rectangular, with straight edges. The heat sink can also be ribbed or smooth. It has a mounting surface where the printed circuit board can be attached to it, which can be a flat surface with or without attachment pins. These pins can be designed to center the printed circuit board on the heat sink, and prevent slippage, thus holding it firmly in place. The mounting surface can be anywhere on the heat sink. In particular, it can be an entire side, or most of one side of the heat sink. This mounting surface can border on the edge of the rectangular heat sink, or it can extend to the edges of the rectangular heat sink. This border can be defined as the outer 10% of a surface of heat sink. A printed circuit board can also be understood to comprise power electronics or a power semiconductor.

The defined insertion point where the tool can be used can be any point on the mounting surface for the printed circuit board. This mounting surface can be in the middle of one side of the heat sink.

The defined insertion point can be a recess, notch, groove, blind hole, through hole, material reduction, press cut, or cut-out in the mounting surface. This insertion point can extend along the entire border of the mounting surface, along all of the borders of the mounting surface, or over just part of the border of the mounting surface. In a preferred embodiment, the defined insertion point can be such that it only provides enough space for the tool itself, such that the tool cannot slip when removing the printed circuit board. This defined insertion point may be made more robust that the rest of the heat sink through an appropriate processing, e.g. with a special coating process, using a special alloy or lacquer. This point can also be coated with a protective layer. This is a good way to prevent damaging the heat sink with the tool.

The tool can be made of a variety of materials, e.g. plastic or metal. It can be a rod that can be easily inserted between the heat sink and the printed circuit board at the defined point. The tip of the tool is ideally tapered slightly to fit the insertion point.

This defined insertion point allows for a quick, inexpensive and user-friendly removal of a printed circuit board glued to a heat sink. In particular, this allows for a convenient recycling and/or reuse or replacement of the heat sink and/or printed circuit board.

In a particularly preferred embodiment of the heat sink, the defined insertion point can be on the border of the mounting surface for the printed circuit board. This means that the defined insertion point can be at the border of the mounting surface. This border where the insertion point is located can be defined as an area extending approx. 0.5 to 3.0 cm in both directions from the edge of the mounting surface. The border of the mounting surface can also be defined as the area extending approx. 0.5 to 3.0 cm from the edge of the heat sink. This means that the border can have an inner and outer boundary. In other words, the defined insertion point can be on the border of the surface to which the printed circuit board is attached. This ensures that the tool can be easily inserted between the printed circuit board and the heat sink in order to pry the printed circuit board off heat sink. The border, or edge, of the heat sink forms a surface for the tool where the printed circuit board can be pried off.

In a particularly preferred embodiment of the heat sink, the defined insertion point can be a recess in the heat sink, which is at least partially within the mounting surface for the printed circuit board. In particular, this defined insertion point has a triangular cross section. In other words, the defined insertion point can be entirely or only partially within the mounting surface for the printed circuit board. This ensures that the tool can be at least partially inserted under the printed circuit board, such that it can be quickly and safely released from the heat sink. This insertion point can have a triangular, rectangular, polygonal, semicircular, or convex cross section. These shapes are particularly well suited for the insertion of a tool, thus preventing the tool from slipping when it is used to remove the printed circuit board.

In another, particularly preferred embodiment of the heat sink, the defined insertion point is formed by a cut-out in the heat sink. In other words, this cut-out can extend through the entire heat sink, formed by drilling or stamping, for example. The cut-out can be a cylindrical or rectangular hole or channel into which the tool can be inserted in order to pry the printed circuit board away from the heat sink. The defined insertion point can also be designed to fit the tool. This requires no leveraging of the tool to insert it through the heat sink in order to push the printed circuit board off. This cut-out is ideally at the edge of the heat sink, such that when the tool passes through the cut-out it pushes against the edge of the printed circuit board where there are no conductive connections. This ensures that the printed circuit board does not become damaged by the tool pushing against it through the cut-out. Another advantage with the cut-out is that the heat sink does not become damaged by the tool passing through it, and the printed circuit board can be quickly removed.

In another preferred embodiment, the defined insertion point can be at the edge of the heat sink near the mounting surface for the printed circuit board, and forms a beveled edge, in particular with an angle of 45°, or a curved edge. In other words, the defined insertion point can be on the edge of the heat sink near the mounting surface where the printed circuit board is glued to it. With this heat sink, the defined insertion point can be a beveled edge, e.g. with an angle of 30° to 60°, preferably with an angle of 45°, or a curved edge, in particular a convex or concave edge. This heat sink has the advantage that the tool can be guided along the edge of the heat sink to efficiently remove the printed circuit board. The edge of the heat sink can form a bearing surface for the tool for prying off the printed circuit board. There can be a longitudinal recess, e.g. a groove, in the beveled or curved edge, preferably in the middle, enabling a particularly precisely defined prying with the tool.

In another particularly preferred embodiment of the invention, the defined insertion point in the heat sink can be a tapering thereof, in particular on the side of the heat sink opposite the mounting surface for the printed circuit board. This tapering can be obtained by removing material from the finished heat sink or by leaving out material during the production of the heat sink. The advantage with this is that the heat sink can be bowed or bent by hand where it is tapered, such that the tool can then be inserted underneath the printed circuit board. By bending the heat sink, mechanical tension is generated between the heat sink and the printed circuit board, resulting in a gap at the edge of the printed circuit board and the heat sink where the tool can be inserted to release the printed circuit board from the heat sink, in particular by prying it away therefrom.

With this heat sink, the printed circuit board is preferably not glued to the heat sink such that it extends to the edge thereof. This allows for a mechanic to hold the heat sink and bend it where it is tapered in order to obtain the gap between it and the printed circuit board.

Numerous defined insertion points can also be formed on the heat sink in a particularly preferred embodiment thereof. In other words, there does not need to be a single defined insertion point, and instead, there can be numerous insertion points, in particular at different locations on the periphery of the printed circuit board. This ensures that if the printed circuit board is difficult to access, at least one defined insertion point remains accessible where the printed circuit board can be released from the heat sink.

In a particularly preferable embodiment of the invention, the defined insertion points can be marked on the heat sink by notches, stamps, coloration and/or machine-readable markings. This marking has the advantage that the defined insertion point can be easily located. If coloring, notching or stamping is used to obtain the marking, the defined insertion point can still be found visually if the heat sink is dirty. These markings, e.g. through coloration, indicate to humans or robots which tool or approach is to be used to release the printed circuit board most easily from the heat sink. A machine-readable marking can enable a partially or fully automated removal of the printed circuit board from the heat sink, in particular by indicating to the person or robot how the printed circuit board is to be released, or the releasing process can be fully automated, thus substantially accelerating the removal. This marker is preferably placed in the immediate proximity of the defined insertion point, in order to indicate the position thereof. The marker, in particular a marker that can be read by a computer, can be placed anywhere on the heat sink to indicate the defined insertion point in relation to the edge of the heat sink to the person or robot removing the printed circuit board therefrom. The marker is ideally placed on the defined insertion point itself.

The heat sink is preferably in a heat sink system for a vehicle headlamp, in particular on a motor vehicle.

A second aspect of the invention relates to a heat sink system that comprises at least one printed circuit board and a heat sink such as that described above. This heat sink system allows for a printed circuit board glued to a heat sink in the heat sink system to be easily, quickly and inexpensively removed.

In a preferred development of the invention, the heat sink system can include a removal tool with which the printed circuit board glued to the heat sink can be easily and quickly released in a defined manner. The tool can be designed to fit the defined insertion point, i.e. in the form of a recess, notch, groove, blind hole, through hole, material reduction, press cut, or cut-out. The tool can be made of a variety of materials, e.g. plastic or metal. In particular, the tool can be a rod that is tapered, in particular flattened, where it is to be inserted into the defined insertion point, so that it can be easily inserted between the heat sink and the printed circuit board at the defined insertion point. This is advantageous when the defined insertion point is a recess, notch, groove, blind hole, or material reduction in one side of the heat sink.

The tool can also be a rod that is not tapered, with which the printed circuit board can be pushed away from the heat sink. This tool is advantageous when the defined insertion point is a through hole, press cut, or cut-out in the heat sink.

By way of example, the tool does not have to be straight, and instead can be curved. In a preferred version, the tool can be rubberized, so that it can be easily held and will not damage the printed circuit board or heat sink during the removal process.

The heat sink system is preferably for a vehicle headlamp, in particular for a motor vehicle.

A third aspect of the invention relates to a vehicle headlamp that contains at least one heat sink system described in the context of the second aspect, and at least one light module. In other words, the vehicle headlamp can contain at least one heat sink system and at least one light module, which can then be connected to the at least one printed circuit board by a wire. The light module can be an LED or numerous LEDs. This type of headlamp, with the heat sink system obtained with the invention, allows for a printed circuit board glued to a heat sink in the heat sink system to be easily, quickly and inexpensively removed therefrom. Consequently, the heat sink and/or printed circuit board in the headlamp can be replaced if necessary.

A fourth aspect of the invention relates to a vehicle. The vehicle contains at least one heat sink described in the context of the first aspect, or a headlamp described in the context of the third aspect of the invention. A vehicle with this type of heat sink or headlamp allows for a printed circuit board glued to the heat sink to be easily, quickly and inexpensively removed therefrom. Consequently, the heat sink or printed circuit board in the headlamp can be replaced if necessary, or recycled if the vehicle is scrapped.

A fifth aspect of the invention relates to a method for releasing a printed circuit board glued to a heat sink of the type described in the context of the first aspect of the invention using a tool, in which the method comprises the following steps: identifying the defined insertion point on the heat sink; placing the tool at the defined insertion point; and prying the printed circuit board away from the heat sink with the tool.

The defined insertion point can be identified automatically or manually. The defined insertion point can be identified directly, or through a marker near the defined insertion point. The insertion point or marker can be detected digitally, optically, or tactilely. The tool can be placed at the insertion point. In other words, the tool is placed at the insertion point such that the printed circuit board can be quickly and safely removed. The information contained in the marker can be used to determine an optimal placement for the tool at the defined insertion point.

Force can be applied to the printed circuit board with the tool in a variety of ways. By way of example, the printed circuit board can be pushed, pressed or pried off of the heat sink. In particular, force can be applied with the tool to the edge of the heat sink as well as the defined insertion point to transfer this force from the tool to the printed circuit board. In particular, the tool can be inserted between the printed circuit board and the heat sink to separate the two.

In a particularly preferred embodiment, the method can be automated. This means that individual steps of the method can be automated, or the entire method can be automated. In particular, the heat sink can first be positioned such that the defined insertion point can be identified, and the printed circuit board can be accessed. The defined insertion point, in particular the marker, can be identified by at least one sensor. The heat sink can then be oriented precisely thereto. The tool can be automatically placed at the defined insertion point, e.g. with a robot arm, lever, or flywheel. The partially or fully automated execution of the method ensures that a printed circuit board glued to a heat sink can be removed from the heat sink inexpensively, efficiently, and without damaging components.

In a particularly preferred embodiment of the method, the tool can be placed in position by a robot arm. This has the advantage that the tool is always placed precisely, with the same force, at the optimal angle, optionally automatically, such that the printed circuit board can be removed without damaging the heat sink or the printed circuit board.

In a particularly preferred embodiment of the method, the force can be applied through a prying or pushing movement by the tool. This application of force can be automated, e.g. using a robot arm, lever, or flywheel. This method can advantageously be carried out particularly inexpensively, quickly, and without damaging the respective components.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1 shows a heat sink with a mounting surface and a defined insertion point, and a removal tool.

FIG. 2 shows a heat sink with a mounting surface and a defined insertion point on the edge of the heat sink.

FIG. 3 shows a heat sink with a mounting surface and a defined insertion point, and a cut X-X through the heat sink.

FIG. 4 shows a cross section X-X through a heat sink, with a defined insertion point that has a triangular cross section.

FIG. 5 shows a cross section X-X through a heat sink with a defined insertion point that has a rectangular cross section.

FIG. 6 shows a cross section X-X though a heat sink with a defined insertion point that has a semicircular cross section.

FIG. 7 shows a heat sink with a defined insertion point in the middle of the mounting surface.

FIG. 8 shows a heat sink with a defined insertion point on the border of the heat sink with a beveled edge.

FIG. 9 shows a heat sink with a defined insertion point on the border of the heat sink with a convex edge.

FIG. 10 shows a heat sink with a defined insertion point on the border of the heat sink with a concave edge.

FIG. 11 shows a defined insertion point in which the back of the heat sink is tapered.

FIG. 12 shows a heat sink with numerous defined insertion points.

FIG. 13 shows a heat sink with a defined insertion point and a marker.

FIG. 14 shows a heat sink system with a printed circuit board and heat sink.

FIG. 15 shows a headlamp that contains a light module and a heat sink system.

FIG. 16 shows a vehicle that has a headlamp.

FIG. 17 shows a flow chart comprising steps S1, S2, and S3.

FIG. 18 shows a robot arm with a releasing tool.

### DETAILED DESCRIPTION OF THE DRAWINGS

In the following descriptions of exemplary embodiments of the invention, the same reference symbols are used for the same features in all of the different exemplary embodiments.

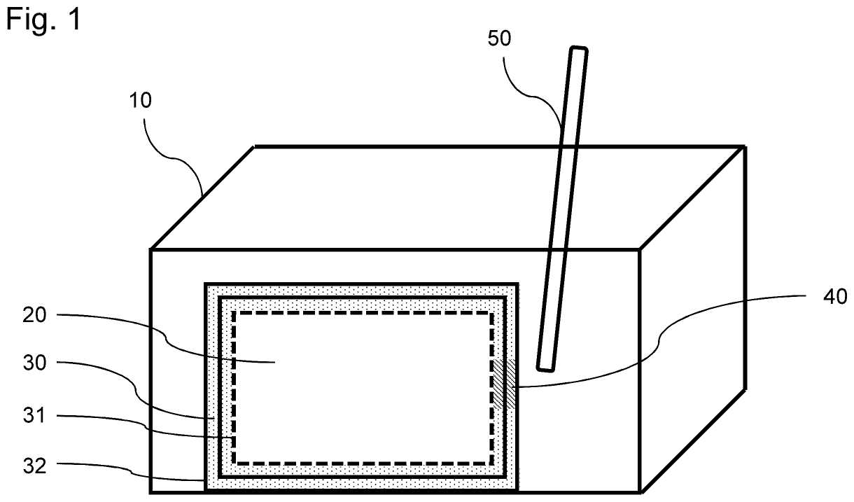

FIG. 1 shows a preferred embodiment of a heat sink 10 that has a defined insertion point 40 on the border 30 of a mounting surface 20. The border 30 of the mounting surface 20 has an inner edge 31 and an outer edge 32. The outer edge 32 and inner edge 32 are 0.5 to 3.0 cm apart from and parallel to the edge of the mounting surface 20. The tool 50 is a rod. A printed circuit board, not shown, is attached to the mounting surface 20 with an adhesive.

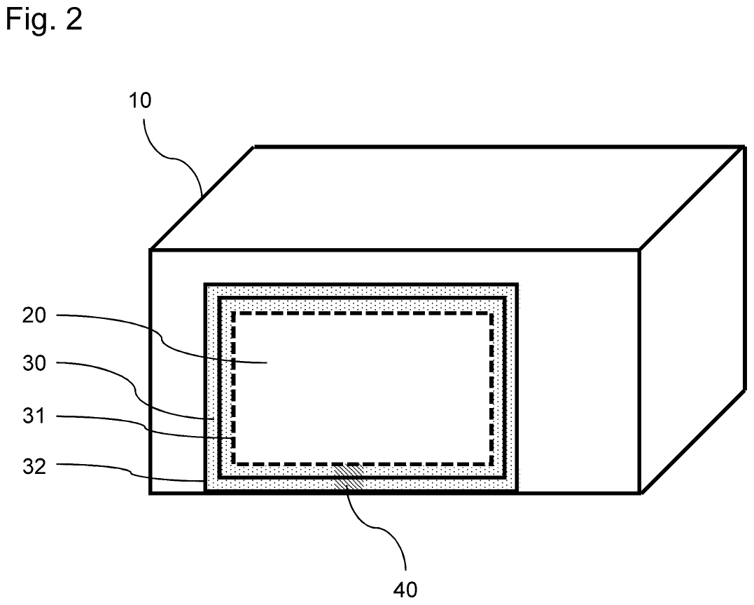

FIG. 2 shows another embodiment of the heat sink 10, in which the defined insertion point 40 is at the border 30 of the mounting surface 20 and on the edge of the heat sink 10. The border 30 of the mounting surface 20 is defined by an outer edge 32 and an inner edge 31. The mounting surface 20 is at the edge of the heat sink 10. The defined insertion point 40 is at a different point on the border 30 of the mounting surface 20 than on the heat sink 10 shown in FIG. 1.

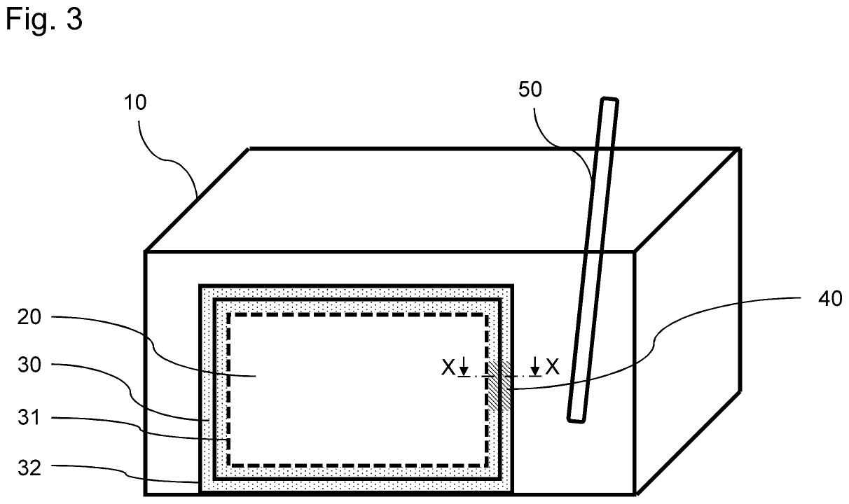

FIG. 3 shows another preferred embodiment of a heat sink 10 with a defined insertion point 40 on the border 30 of a mounting surface 20. The border 30 of the mounting surface 20 has an inner edge 31 and an outer edge 32. A lateral cut X-X through the defined insertion point 40 is indicated.

A tool 50 that can be placed at the defined insertion point 40 on the heat sink 10 to release a printed circuit board 33 therefrom is also shown in FIGS. 1 to 3.

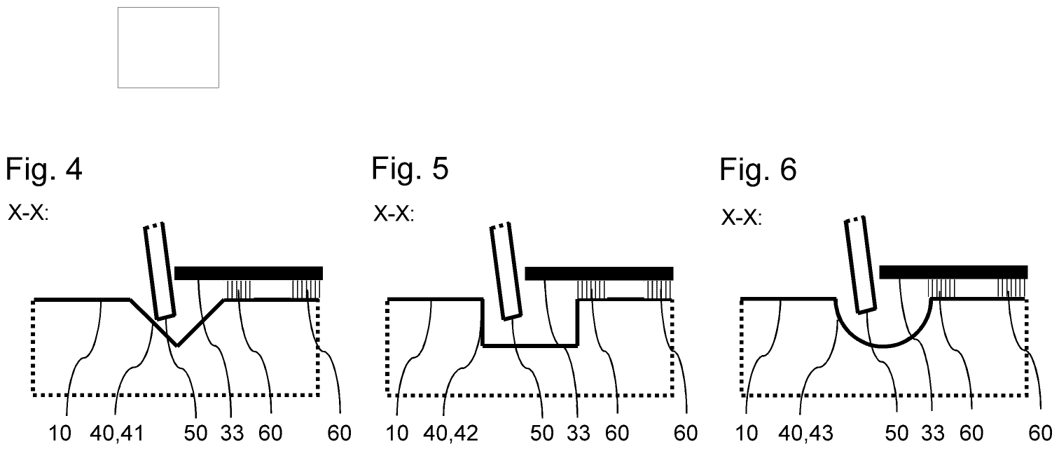

FIGS. 4, 5, and 6 each show a cross section along the cut X-X in FIG. 3, containing a printed circuit board 33, adhesive 60, and the tool 50. FIGS. 4, 5, and 6 also show a cross section of the defined insertion point 40. The defined insertion point 40 has a triangular cross section 41 in FIG. 4, a rectangular cross section 42 in FIG. 5, and a semicircular or curved cross section 43 in FIG. 6. All three FIGS. 4, 5 and 6 show how the tool 40 is placed under the printed circuit board 33 to easily pry it from the heat sink 10 in the next step without causing any damage.

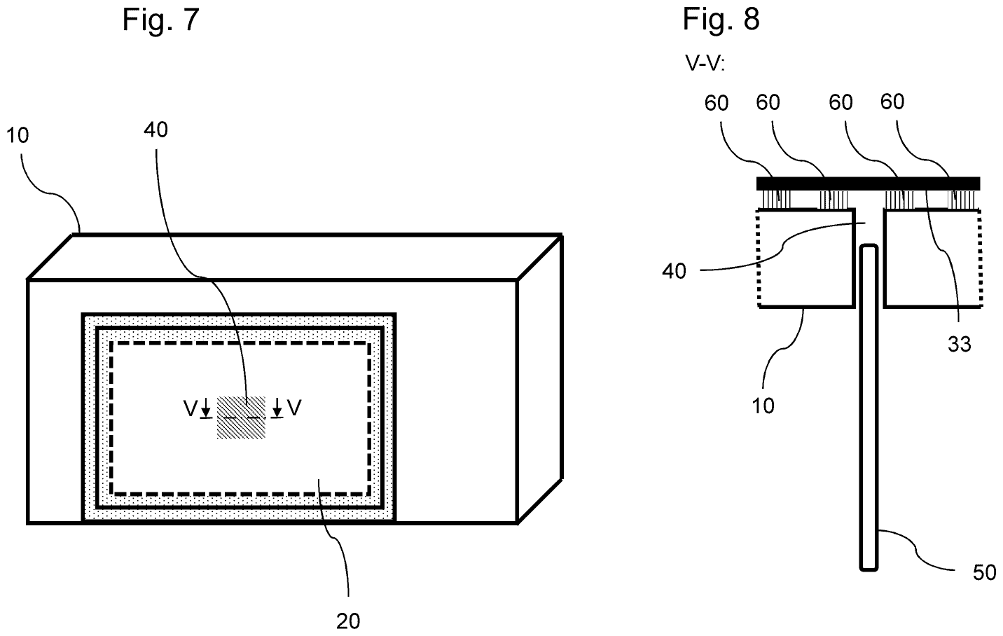

FIG. 7 shows an embodiment of the heat sink 10 in which the defined insertion point 40 is in the middle of the mounting surface 20. A cut V-V through the mounting surface 20 of the heat sink 10 is also shown, see FIG. 8. This cross section along the cut V-V shows the defined insertion point 40 as a through hole, or a channel, through the heat sink 10. The tool 50 is inserted into this hole, or channel, to release the printed circuit board 33 attached to the mounting surface 20 on the heat sink 10 with adhesive 60.

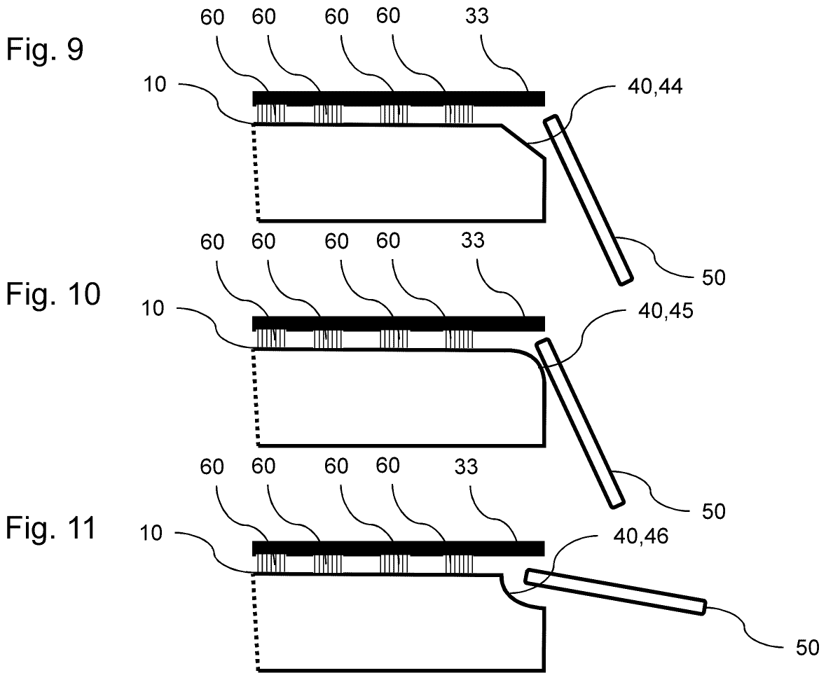

FIGS. 9, 10 and 11 each show a printed circuit board 33, adhesive 60, a tool 60, and a heat sink 10 with a defined insertion point 40. The defined insertion point 40 has a beveled edge 44 in FIG. 8, a convex edge 45 in FIG. 9, and a concave edge 46 in FIG. 10. The tool 50 is placed at the defined insertion point 40 in all three embodiments, and is slid along it to pry the printed circuit board 33 from the heat sink 10.

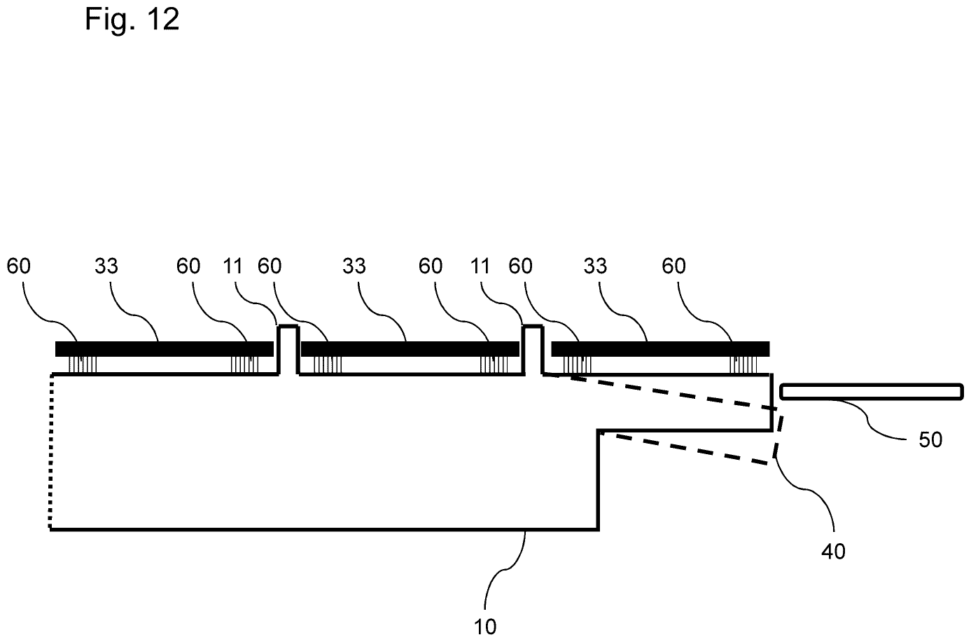

FIG. 12 shows an embodiment of the defined insertion point 40 in which the heat sink 10 is tapered at the back. The defined insertion point 40 can be bent downward, specifically by hand, to form a gap between the heat sink 10 and the printed circuit board 33 where the tool 50 can be inserted. The attachment pins 11 only pass through the printed circuit board 33 in points, thus allowing it to be released with the tool 50 at the defined insertion point 40.

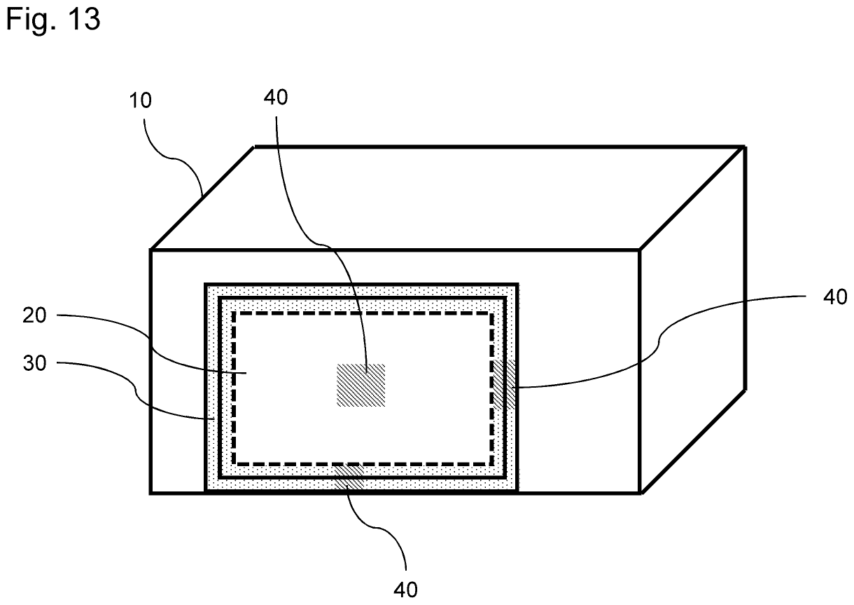

FIG. 13 shows another heat sink 10 with numerous defined insertion points 40, one of which is in the middle of the mounting surface 20, while another is formed on the longer border 30 of the mounting surface 20, and a third is formed on the shorter border 30 of the mounting surface 20, at the edge of the heat sink 10.

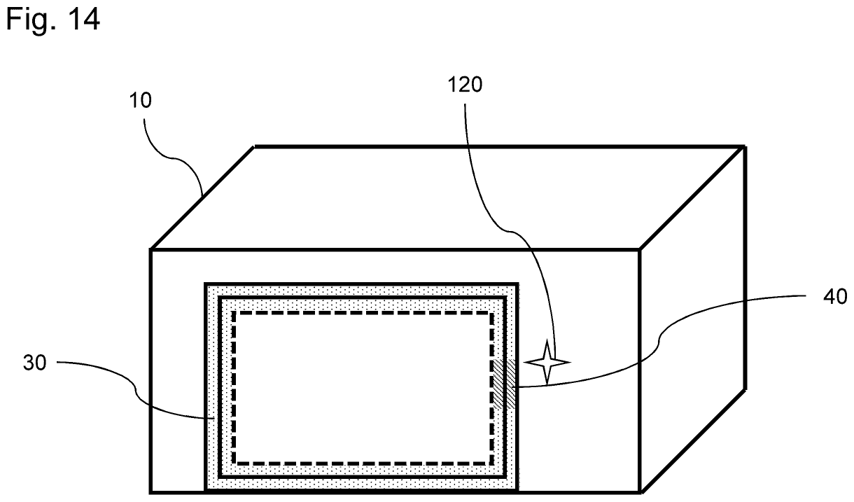

FIG. 14 shows a marker 120 indicating the location of the defined insertion point 40 on the border 30 of the mounting surface 20 on the heat sink 10. The marker 120 can be a notch, press cut, coloration, and/or a machine-readable marking. The marker 120 is placed on the defined insertion point 40 or directly adjacent thereto. This advantageously simplifies loctating the defined insertion point. With a colored marking, a notch, or a press cut, the defined insertion point 40 can be easily seen, such that the tool 50 can be placed at the defined insertion point 40 manually by a person, or automatically by a robot, where it can then be used to pry the circuit board away from the heat sink.

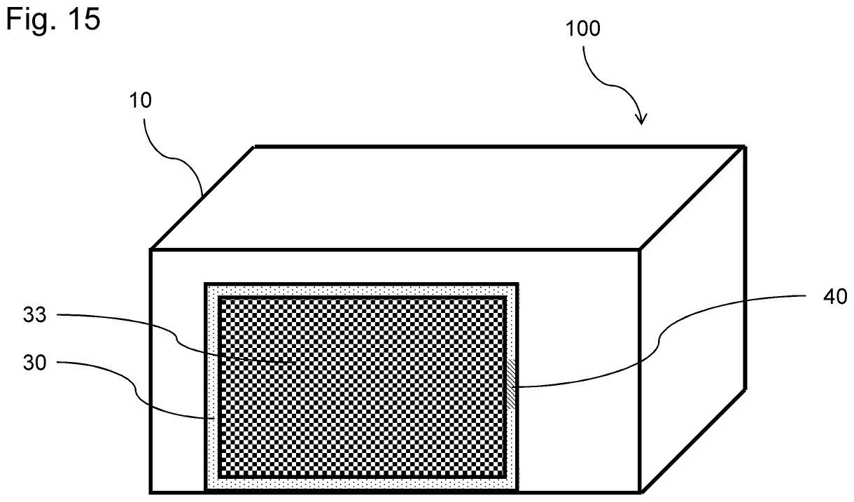

FIG. 15 shows a heat sink system 100 that contains a heat sink 10, a printed circuit board 33 glued to the mounting surface 20 on the heat sink 10, and a defined insertion point 40 on the border 30 of the mounting surface 20.

FIG. 15 shows a headlamp 110, in which the light module 70 is connected to the heat sink system 100 by a wire 71. The heat sink system 100 contains a heat sink and a printed circuit board 33. There is a defined insertion point 40 on the border 30 of the mounting surface 20.

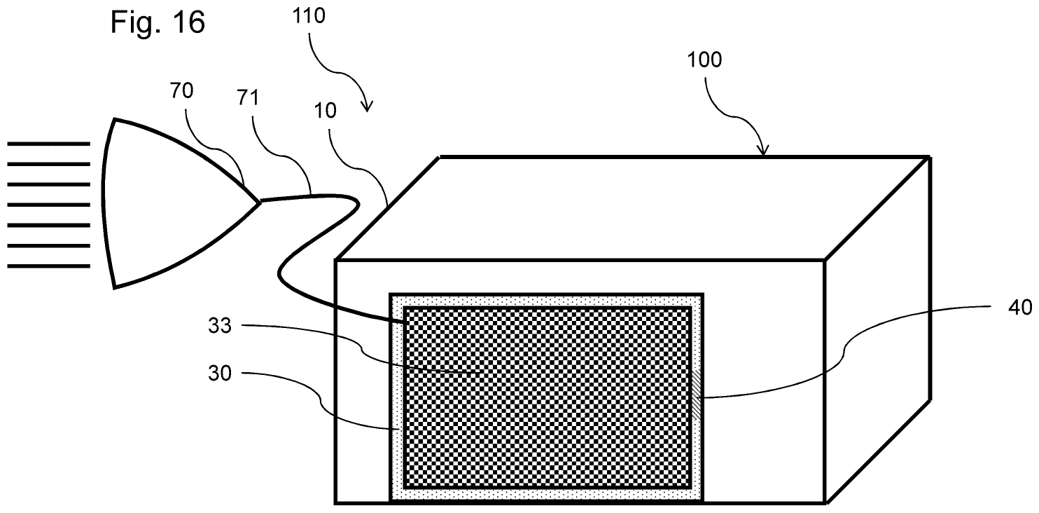

A headlamp 110 is shown in FIG. 16, which is connected to the heat sink system 100 shown in FIG. 16, and contains a light module 70. The light module 70 is connected to the printed circuit board 33 by a wire 71.

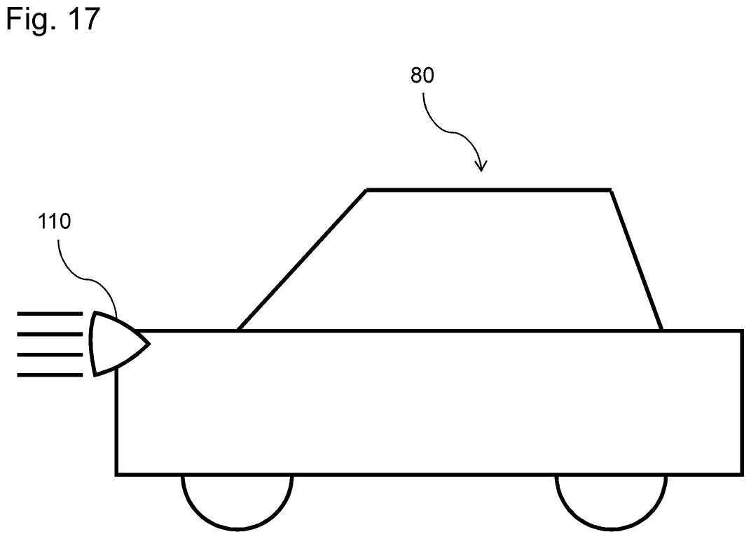

FIG. 17 shows a vehicle 80 that has a headlamp 110 like that shown in FIG. 16.

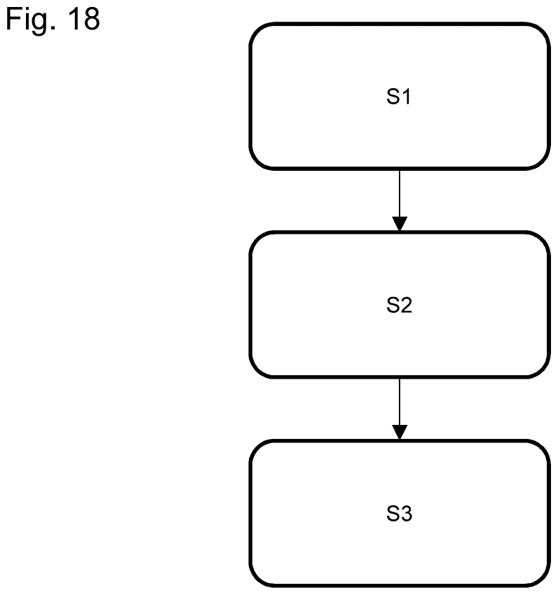

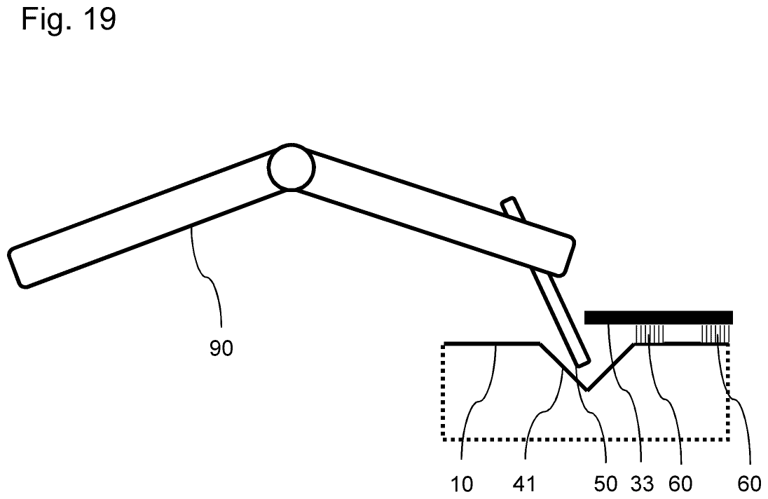

FIG. 18 shows a flow chart for the method for releasing a printed circuit board 33 glued to a heat sink 10 using a tool 50, in which the method comprise the following steps: S1 identifying the defined insertion point 40, S2 placing the tool 50 at the defined insertion point 40, S3 releasing the printed circuit board 33 from the heat sink 10 with the tool 50.

FIG. 19 shows a robot arm 90 placing the tool 50 in the defined insertion point 40, which has a triangular cross section 41, in order to pry the printed circuit board 33 from the heat sink 10, which is held thereon by an adhesive 60.

The above explanations of the embodiments describe the present invention exclusively in the framework of examples. As a matter of course, individual features of the embodiments can be freely combined with one another, as long as this makes sense from a technical perspective, without abandoning the framework of the present invention.

### LIST OF REFERENCE SYMBOLS

10 heat sink
11 attachment pins
20 mounting surface for attaching a printed circuit board
30 border of the mounting surface
31 inner edge of the border of the mounting surface
32 outer edge of the border of the mounting surface
33 printed circuit board
40 defined insertion point
41 triangular cross section
42 rectangular cross section
43 curved cross section
44 beveled cross section
45 curved edge
46 curved edge
50 tool
60 adhesive
70 light module
71 wire
80 vehicle
90 robot arm
100 heat sink system
110 headlamp
120 marker
S1 step 1
S2 step 2
S3 step 3

1. A heat sink comprising:
a mounting surface to which a printed circuit board is attached using an adhesive;
a defined insertion point adapted for a tool to pry the printed circuit board away from the heat sink.

2. The heat sink according to claim 1, wherein the defined insertion point is on a border of the mounting surface.

3. The heat sink according to claim 1, wherein the defined insertion point is a recess in the heat sink, which is at least partially within the mounting surface.

4. The heat sink according to claim 1, wherein the defined insertion point is a cut-out through the heat sink.

5. The heat sink according to claim 1, wherein the defined insertion point is on an edge of the heat sink where the mounting surface is located, wherein the defined insertion point is a beveled edge.

6. The heat sink according to claim 1, wherein the defined insertion point is a tapering of the heat sink.

7. The heat sink according to claim 1, wherein numerous defined insertion points are formed on the heat sink.

8. The heat sink according to claim 1, wherein the defined insertion point is indicated by a marker.

9. A heat sink system, comprising:
at least one printed circuit board; and
a heat sink according to claim 1.

10. A headlamp for a vehicle, the headlamp comprising at least one heat sink system according to claim 9, and at least one light module.

11. A method for releasing a printed circuit board glued to a heat sink according to claim 1 using a tool, wherein the method contains the following steps:
identifying the defined insertion point;
placing the tool at the identified defined insertion point; and
prying the printed circuit board away from the heat sink using the tool.

12. The method according to claim 11, wherein the method is automated.

13. The method according to claim 11, wherein the tool is manipulated by a robot arm.

14. The method according to claim 1, wherein the tool is used to pry or push the printed circuit board away from the heat sink.

15. The heat sink according to claim 3, wherein the defined insertion point has a triangular cross section.

16. The heat sink according to claim 5, wherein the defined insertion point is a beveled edge with an angle of 45° or a curved edge.

17. The heat sink according to claim 6, wherein the defined insertion point is a tapering of the heat sink on the side opposite the mounting surface.

18. The heat sink according to claim 8, wherein the marker is formed by a notch, press cut, coloration, and/or a machine-readable marking.
